(19) United States
(12) Patent Application Publication
(10) Pub. No.: US 2004/0245651 A1
(43) Pub. Date: Dec. 9, 2004

(54) Semiconductor device and method for fabricating the same

(75) Inventors: Takashige Nishisako, Kyoto (JP); Yasuhiro Ishiyama, Shiga (JP); Hisakazu Kotani, Hyogo (JP)

Correspondence Address: Jack Q. Lever, Jr., McDERMOTT, WILL & EMERY, 600 Thirteenth Street, N.W., Washington, DC, 20005-3096, US

(73) Assignee: MATSUSHITA ELECTRIC INDUSTRIAL CO., LTD.

(21) Appl. No.: 10/456,846

(22) Filed: Jun. 9, 2003

(51) Int. Cl. H01L 21/44; H01L 23/48; H01L 29/40

(52) U.S. Cl. 257/777; 257/778; 438/106; 438/108

(57) ABSTRACT

A first inventive semiconductor device includes: a die pad 1; a mother chip 2; a daughter chip 3; a conductor film 7 formed on the back surface of the daughter chip 3; bumps 4; a lead 5; and a bonding wire 6, as shown in FIG. 1B. The conductor film 7 is connected to an external member via the bonding wire 6 and the lead 5, thus stabilizing a substrate potential. In addition, the conductor film 7 has a high heat conductivity and a low electrical resistance, thereby improving the heat radiation performance of the semiconductor device and suppressing noise radiation.

### BACKGROUND OF THE INVENTION

The present invention relates to semiconductor devices and methods for fabricating the same, and more particularly, to multifunction semiconductor devices such as system LSIs utilizing an SIP technique and methods for fabricating the same.

Recently, with the progress of semiconductor technology, system LSIs have become mainstream which each implement, on a single semiconductor chip, a system that had been previously implemented on a board.

In most system LSIs, memories such as a DRAM and a flash memory are combined on a chip. However, such system LSIs have confronted a problem that these memories to be combined have not been downsized so rapidly as compared to logic sections to be also combined on the same chip and a problem that it takes a long time and is difficult to develop the process for combining such components on a chip.

Under such circumstances, a system in package (SiP) technique for implementing a system LSI by molding a plurality of semiconductor chips in a single package has received attention. The SiP technique is divided into two major types according to configurations. A first type is a process for mounting a chip to be bonded (hereinafter, referred to as a daughter chip) to a semiconductor chip to be a base (hereinafter, referred to as a mother chip) via bumps with the chips placed face-to-face. This type is called a face-down process because the daughter chip faces downward. A second type is a process for bonding the back surface of a daughter chip onto a mother chip. In this process, these chips are connected directly or connected with a bonding wire via a lead. This type is called a face-up process because the daughter chip faces upward.

FIGS. 12A and 12B are cross-sectional views showing respective structures of known semiconductor devices. The semiconductor device shown in FIG. 12A has a known face-down configuration including: a die pad 201; a mother chip 202 provided on the die pad 201; a daughter chip 203 mounted to the mother chip 202 and facing downward; bumps 204 connecting the mother chip 202 to the daughter chip 203; a lead 205 for connecting the mother chip 202 to an external component; and a bonding wire 206 for electrically connecting the mother chip 202 to the lead 205. On the other hand, the semiconductor device shown in FIG. 12B includes: a die pad 211; a mother chip 212 provided on the die pad 211; a daughter chip 213 mounted on the mother chip 212 and facing upward; a lead 215 for connecting the mother and daughter chips 202 and 203 to an external component; and a bonding wire 216 for electrically connecting the mother chip 212 to the lead 215.

However, the known semiconductor devices have the following problems.

Firstly, in the SiP technique, the durability of the known devices against noise or heat is reduced because of downsizing of a process rule attained by the progress of technology. On the other hand, the voltage at the power source has been reduced and the operating frequency has been increased at increasingly fast rates. As a result, there arise problems such as increase in radiation noise, increase in heat generation from the chips and deterioration of radiation efficiency. These problems lead to a malfunction.

In the case of the face-down configuration, bonding pads provided on the daughter chip are hidden after the packaging. As a result, it is impossible to test the daughter chip alone via the connecting pads. Further, the area of a chip region in wafer state is not effectively secured.

On the other hand, in the case of the face-up configuration, long bonding wires for electrical connection are need, so that noise caused by crosstalk to an adjacent terminal has a great influence. In addition, contamination is liable to occur within the device because of a glue used for bonding the chips. Furthermore, the chip orientation might be misidentified in connecting the chips.

### SUMMARY OF THE INVENTION

It is therefore an object of the present invention to provide a highly reliable semiconductor device which can be further downsized and a method for fabricating the same, by taking measures for solving the problems above discussed.

Specifically, a first inventive semiconductor device includes: a first semiconductor chip; a second semiconductor chip mounted to the first semiconductor chip; and a conductor film formed on a back surface of the second semiconductor chip and electrically connected to a connecting member connected to a potential-stabilizing member.

In this structure, the conductor film having a high heat conductivity and a low electrical resistance is in contact with the back surface of the second semiconductor chip, thereby improving the heat radiation performance and enabling a stabilized potential at the second semiconductor chip. In addition, it is possible to prevent noise from being transmitted from the first and second semiconductor chips to the surroundings.

The second semiconductor chip may be mounted to the first semiconductor chip with a principal surface of the second semiconductor chip facing downward.

The conductor film preferably extends from on the back surface of the second semiconductor chip onto a portion of the first semiconductor chip.

The second semiconductor chip may be mounted to the first semiconductor chip with a principal surface of the second semiconductor chip facing upward, part of the conductor film may be sandwiched between the first and second semiconductor chips, and the other part of the conductor film may be exposed on the first semiconductor chip and be in contact with the connecting member. Then, it is possible to prevent noise from being transmitted from the first semiconductor chip to the second semiconductor chip.

The second semiconductor chip may be provided in a plural presence over the first semiconductor chip, and the conductor film may cover the back surfaces of the plurality of second semiconductor chips. Then, the conductor film is formed on the back surfaces of the plurality of second semiconductor chip at a time.

A second inventive semiconductor device includes: a first semiconductor chip; a conductor pattern provided on the top of the first semiconductor chip and electrically connected to a potential-stabilizing member; a first-chip-side connecting pad provided on the top of the first semiconductor chip and insulated from the conductor pattern; a second semiconductor chip mounted to the first semiconductor chip with a principal surface of the second semiconductor chip facing downward; and a second-chip-side connecting pad provided on the bottom of the second semiconductor chip and electrically connected to the first-chip-side connecting pad. The conductor pattern and the first-chip-side connecting pad are patterned out of an identical film.

In this structure, the conductor pattern having a high heat conductivity and a low electrical resistance is located under the second semiconductor chip, thereby achieving a stabilized substrate potential. In addition, the conductor pattern acts as a noise shield, thereby preventing noise from being transmitted from the first semiconductor chip to the second semiconductor chip.

The potential-stabilizing-member may be a power source line for the first semiconductor chip.

A third inventive semiconductor device includes: a first semiconductor chip; a second semiconductor chip mounted to the first semiconductor chip with a principal surface of the second semiconductor chip facing downward; and a second-chip-side connecting member provided on the bottom of the second semiconductor chip; and a testing member electrically connected to the second-chip-side connecting member, at least part of the second-chip-side connecting member being located outside the second semiconductor chip when viewed vertically to the second semiconductor chip.

In this structure, even after the second semiconductor chip has been mounted, it is possible to the second or first semiconductor chip independently of each other by using the testing member.

The part of the testing member may be located in a peripheral portion of the second semiconductor chip when viewed vertically to the second semiconductor chip, and the second semiconductor chip may be accessible to external equipment with the testing member.

The testing member may be formed on the top of the first semiconductor chip, and the testing member may be connected to the second-chip-side connecting member via a wire. Then, it is possible to test the first and second semiconductor chips using the same testing member after the second semiconductor chip has been mounted to the first semiconductor chip on which the testing member had been formed beforehand.

A first-chip-side connecting member may be provided on the top of the first semiconductor chip, and the part of the testing member may extend outwardly beyond a region of the first semiconductor chip where the second semiconductor chip is formed, and the other part of the testing member may be sandwiched between the first-chip-side connecting member and the second-chip-side connecting member. Then, the sandwiching of the testing member in mounting the second semiconductor chip to the first semiconductor chip enables the first and second semiconductor chips to be tested using the same testing member.

Part of the testing member is preferably covered with an insulator film. Then, it is possible to prevent a short circuit between testing members.

The semiconductor device may further include a circuit for activating the first and second semiconductor chips individually in accordance to signals applied to the testing member. Then, the first and second semiconductor chips can be controlled independently of each other.

A fourth inventive semiconductor device includes: a first semiconductor chip; a second semiconductor chip mounted to the first semiconductor chip with a principal surface of the second semiconductor chip facing downward; a second-chip-side connecting member provided on the top of the second semiconductor chip; and a wire, which is connected to the second-chip-side connecting member and was located on a scribe lane in a wafer state.

In this structure, it is possible to test the second semiconductor chip in wafer state using the testing member mounted on the scribe lane. The testing member can be separated from the second semiconductor chip after the test. Thus, the area of the second semiconductor chip can be reduced.

A fifth inventive semiconductor device includes: a first semiconductor chip; a first-chip-side connecting member provided on the top of the first semiconductor chip; a second semiconductor chip mounted to the first semiconductor chip with a principal surface of the second semiconductor chip facing downward; and a wire, which is connected to the first-chip-side connecting member and was located on a scribe lane in a wafer state.

In this structure, it is possible to test the first semiconductor chip in wafer state using the testing member mounted on the scribe lane. The testing member can be separated from the first semiconductor chip after the test. Thus, the area of the first semiconductor chip can be reduced.

A sixth inventive semiconductor device includes: a base; a semiconductor chip mounted on the base; first and second terminals provided on part of the semiconductor chip; a signal-transmitting wire having two terminals, one of which is connected to the first terminal and the other of which is connected to a first external terminal; and one or more shield wires for removing noise in the signal-transmitting wire, each of the shield wires being located at a side of the signal-transmitting wire and having two terminals, one of which is connected to the second terminal and the other of which is connected to a second external terminal.

In this structure, the shield wires located around the signal-transmitting wire act as shields, so that the signal-transmitting wire is less effected by noise from the surroundings.

The first and second external terminals are provided outside the semiconductor chip.

The signal-transmitting wire may be sandwiched between the shield wires. Then, the signal-transmitting wire is less effected by noise as intended.

The base may be a second semiconductor chip; third and fourth terminals may be further provided on parts of the second semiconductor chip, the third terminal may be connected to a second signal-transmitting wire having a terminal connected to a third external terminal, and one or more second shield wires for protecting the second signal-transmitting wire may be further provided, and each of the second shield wires may be located at a side of the second signal-transmitting wire and has two terminals, one of which is connected to the fourth terminal and the other is connected to a fourth external terminal. In particular, it is possible to effectively suppress the influence of noise that is liable to be serious in the case of a SiP technique because the length of the signal-transmitting wire increases.

The third and fourth external terminals are provided outside the semiconductor chip and the second semiconductor chip.

The second and fourth external terminals are preferably in an identical power source ring connected to a power source line. Then, a smaller number of external terminals can be provided.

The second and fourth terminals are preferably made of an identical conductor film intervening between the semiconductor chip and the second semiconductor chip. Then, a smaller number of second and fourth terminals can be provided.

A seventh inventive semiconductor device includes: a first semiconductor chip; a second semiconductor chip mounted to the first semiconductor chip; an adhesive for bonding the first and second semiconductor chips together; and an adhesive stopper for preventing the adhesive from expanding, the adhesive stopper being formed on the first semiconductor chip.

In this structure, it is possible to prevent the first semiconductor chip, for example, from being contaminated by the adhesive.

An eighth inventive semiconductor device includes: a first semiconductor chip; a second semiconductor chip mounted to the first semiconductor chip; and a connecting member for identifying an orientation of the first semiconductor chip when viewed vertically to the first semiconductor chip, the connecting member being formed on the first semiconductor chip.

In this structure, it is possible to prevent misidentification of orientation of the second semiconductor chip in mounting the second semiconductor chip to the first semiconductor chip.

An inventive method for fabricating a semiconductor device in which a second semiconductor chip is mounted to a first semiconductor chip includes the steps of a) forming a first-chip-side connecting member on part of the first semiconductor chip; b) forming a second-chip-side connecting member on part of the second semiconductor chip; and c) mounting the second semiconductor chip to the first semiconductor chip with part of a testing member sandwiched between the first-chip-side connecting member and the second-chip-side connecting member.

With this method, it is possible to test the first and second semiconductor chips independently of each other using the testing member even after the step c) has been performed.

At least part of the side of the testing member may be covered with an insulator film, and in the step c), the second semiconductor chip may be mounted to the first semiconductor chip with a pressure applied thereto. Then, it is possible to prevent a short circuit between testing members.

### BRIEF DESCRIPTION OF THE DRAWINGS

FIGS. 1A through 1C are cross-sectional views showing respective structures of semiconductor devices according to a first embodiment.

FIGS. 2A and 2B are respectively a plan view and a cross-sectional view taken along the line II-II and show a process of connecting a mother chip and a daughter chip in a first semiconductor device according to a second embodiment.

FIGS. 3A and 3B are respectively a plan view and a cross-sectional view taken along the III-III line and show a process of connecting a mother chip and a daughter chip in a second semiconductor device according to the second embodiment.

FIGS. 4A through 4C are plan views and an electronic circuit diagram showing a structure of a semiconductor device with a face-down configuration according to a third embodiment.

FIGS. 5A through 5C are plan views showing chips in wafer state according to a fourth embodiment FIGS. 6A through 6F are plan views and a perspective view showing process steps for mounting a daughter chip to a mother chip in a process for fabricating the semiconductor device of a fifth embodiment.

FIGS. 7A through 7D are plan views showing process steps for mounting a daughter chip to a mother chip in a process for fabricating the semiconductor device of a sixth embodiment.

FIGS. 8A and 8B are plan views showing structures of semiconductor devices according to a seventh embodiment.

FIG. 9 is a plan view showing a structure of a semiconductor device according to the seventh embodiment.

FIGS. 10A and 10B are respectively a plan view and a cross-sectional view taken along the line X-X and show a structure of a semiconductor device of an eighth embodiment.

FIG. 11 is a plan view showing a mother chip before a daughter chip is mounted thereon in a ninth embodiment.

FIGS. 12A and 12B are cross-sectional views showing respective structures of known semiconductor devices.

### DESCRIPTION OF THE PREFERRED EMBODIMENTS

Embodiment 1

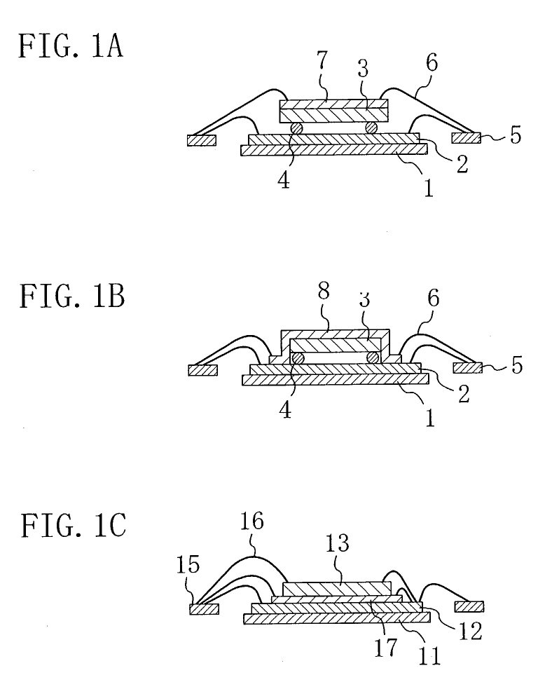

Hereinafter, a first embodiment of the present invention will be described with reference to FIGS. 1A through 1C.

FIGS. 1A and 1B are cross-sectional views showing respective structures of semiconductor devices with face-down configurations according to this embodiment.

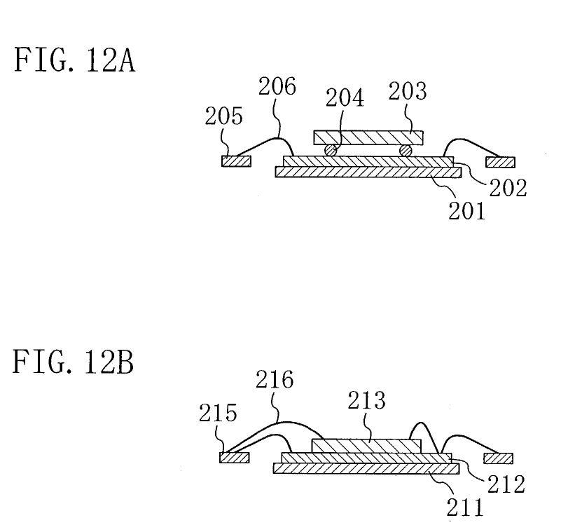

As shown in FIG. 1A, a first semiconductor device with a face-down configuration according to this embodiment has a structure in which a conductor film is formed on the back surface of a daughter chip 203 as described in the known semiconductor device shown in FIG. 12A. Specifically, the first semiconductor device shown in FIG. 1A includes: a die pad 1; a mother chip 2 with a thickness of 50 to 200 μm provided on the die pad 1; a daughter chip 3 with a thickness of 50 to 200 μm mounted to the mother chip 2 with the principal surface of the daughter chip 3 facing downward; a conductor film 7 formed on the back surface (upper surface) of the daughter chip 3; bumps 4 connecting the mother chip 2 to the daughter chip 3; a lead 5 for connecting the mother chip 2 to an external component; and a bonding wire 6 electrically connecting the mother chip 2 to the lead 5. In this case, each of the mother and daughter chips 2 and 3 may have a thickness of 50 μm or less.

The conductor film 7 has a high thermal conductivity and a low electrical resistance, as compared to Si that mainly constitutes the daughter chip 3. Thus, the conductor film 7 improves heat radiation and suppresses noise radiation from the mother chip 2 and the daughter chip 3. In addition, the conductor film 7 is electrically connected to an external component via the bonding wire 6 and the lead 5, thereby stabilizing the substrate potential.

If this embodiment is applied to an SiP technique which exhibits a great influence of noise and poor heat radiation because the semiconductor chips are vertically stacked, significant advantages are obtained.

As shown in FIG. 1B, a second semiconductor device with a face-down configuration according to this embodiment has a structure in which a daughter chip 203 as described in the known semiconductor device shown in FIG. 12A is covered with a conductor film. Specifically, the second semiconductor device shown in FIG. 1B includes: a die pad 1; a mother chip 2 provided on the die pad 1; a daughter chip 3 mounted to the mother chip 2 with the principal surface of the daughter chip 3 facing downward; bumps 4 connecting the mother chip 2 to the daughter chip 3; a lead 5 for connecting the mother chip 2 to an external component; a bonding wire 6 electrically connecting the mother chip 2 to the lead 5; and a conductor film 8 covering the daughter chip 3. Because of the conductive film 8, the same advantages as in the first semiconductor device shown in FIG. 1A are obtained. Further, the second semiconductor device has another advantage that a plurality of daughter chips can be covered with the conductor film 8 at a time.

FIG. 1C is a cross-sectional view showing a structure of a semiconductor device with a face-up configuration according to this embodiment. As shown in FIG. 1C, a semiconductor device with a face-up configuration according to this embodiment has a structure in which a conductor film is sandwiched between mother and daughter chips 212 and 213 as described in the known semiconductor device shown in FIG. 12B. Specifically, the semiconductor device shown in FIG. 1C includes: a die pad 11; a mother chip 12 provided on the die pad 11; a daughter chip 13 mounted to the mother chip 12 with the principal surface of the daughter chip 13 facing upward; a conductor film 17 sandwiched between the mother chip 12 and the daughter chip 13; a lead 15 for connecting the mother chip 12 to an external component; and a bonding wire 16 electrically connecting the mother chip 12 to the lead 15. Because of the conductive film 17, the substrate potential at the daughter chip 13 is stabilized and heat radiation is improved. In addition, the conductor film 17 acts as a noise shield and the conductor film 17 and the die pad 11 constitute a capacitor, thereby preventing noise radiation from the mother chip 12 from affecting the daughter chip 13. Furthermore, a plurality of daughter chips 13 can be formed at a time on the single conductor film 17.

Embodiment 2

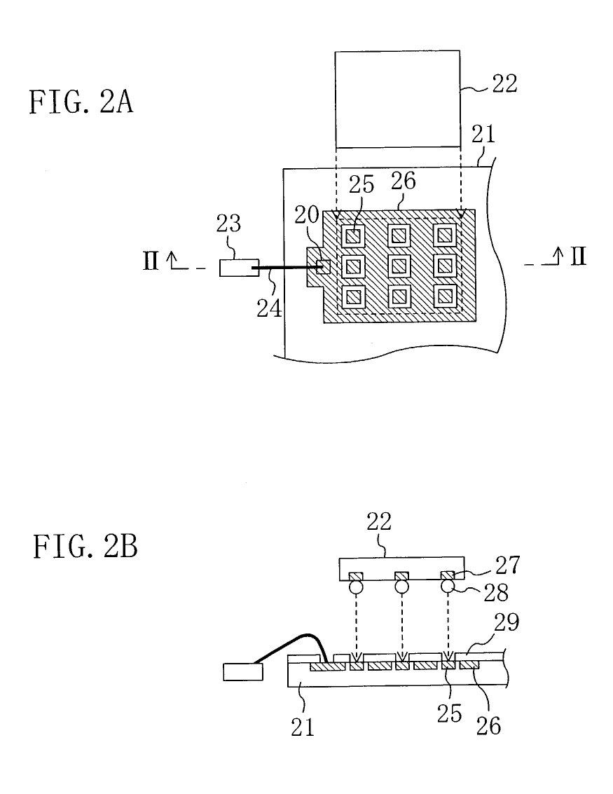

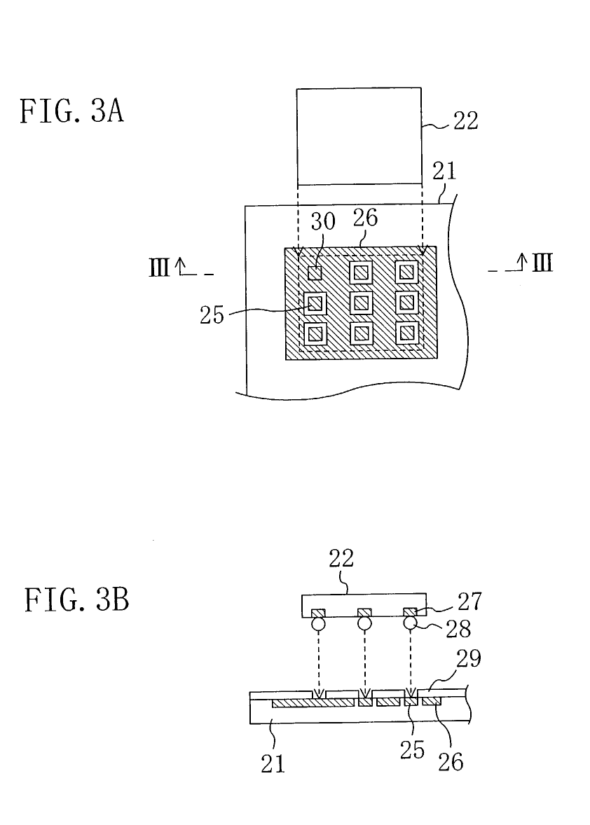

Hereinafter, a second embodiment of the present invention will be described with reference to FIGS. 2A and 2B and FIGS. 3A and 3B.

FIGS. 2A and 2B are respectively a plan view and a cross-sectional view taken along the line II-II and show a process of connecting a mother chip and a daughter chip in a first semiconductor device according to this embodiment. The first semiconductor device of this embodiment has a face-down configuration and includes: a mother chip 21 with a thickness of 50 to 200 μm; a daughter chip 22 with a thickness of 50 to 200 μm mounted to the mother chip 21; a lead 23 for connecting the mother chip 21 to an external component; and a bonding wire 24 connecting the lead 23 to a potential-fixing pad 20 provided on the mother chip 21. In this case, each of the mother and daughter chips 21 and 22 may have a thickness of 50 μm or less.

Connecting pads 25 of a conductor are formed in part of the upper surface of the mother chip 21. A conductor pattern 26 is formed in another part of the upper surface of the mother chip 21 so as to surround the connecting pads 25, being insulated from the connecting pads 25 with an insulator. The conductor pattern 26 is connected to the lead 23 via the potential-fixing pad 20 and the bonding wire 24. Connecting pads 27 of a conductor are formed in part of the lower surface of the daughter chip 22. Bumps 28 are formed on the respective lower surfaces of the connecting pads 27. The connecting pads 25 in the mother chip 21 are connected to the connecting pads 27 in the daughter chip 22 via the bumps 28. Although not shown in FIG. 2A but shown only in FIG. 2B, a passivation film 29 covers part of the upper surface of the mother chip 21 other than the parts thereof where the connecting pads 25 are in contact with the bumps 28 and where the potential-fixing pad 20 is formed.

In the first semiconductor device of this embodiment, the conductor pattern 26 acts as a noise shield, thereby preventing noise radiation from the mother chip 21 toward the daughter chip 22.

FIGS. 3A and 3B are respectively a plan view and a cross-sectional view taken along the line III-III and show a process of connecting a mother chip and a daughter chip in a second semiconductor device according to this embodiment. In the second semiconductor device of this embodiment, a potential-fixing pad 30 is formed in part of the mother chip 21, instead of the lead 23 and the bonding wire 24 of the first semiconductor device shown in FIGS. 2A and 2B. The potential-fixing pad 30 is connected to a power source line (V_{DD} or V_{SS}) for the mother chip 21, thereby stabilizing the potential at the mother chip 21. The semiconductor device shown in FIGS. 3A and 3B also attains the same advantages as in the semiconductor device shown in FIGS. 2A and 2B.

Embodiment 3

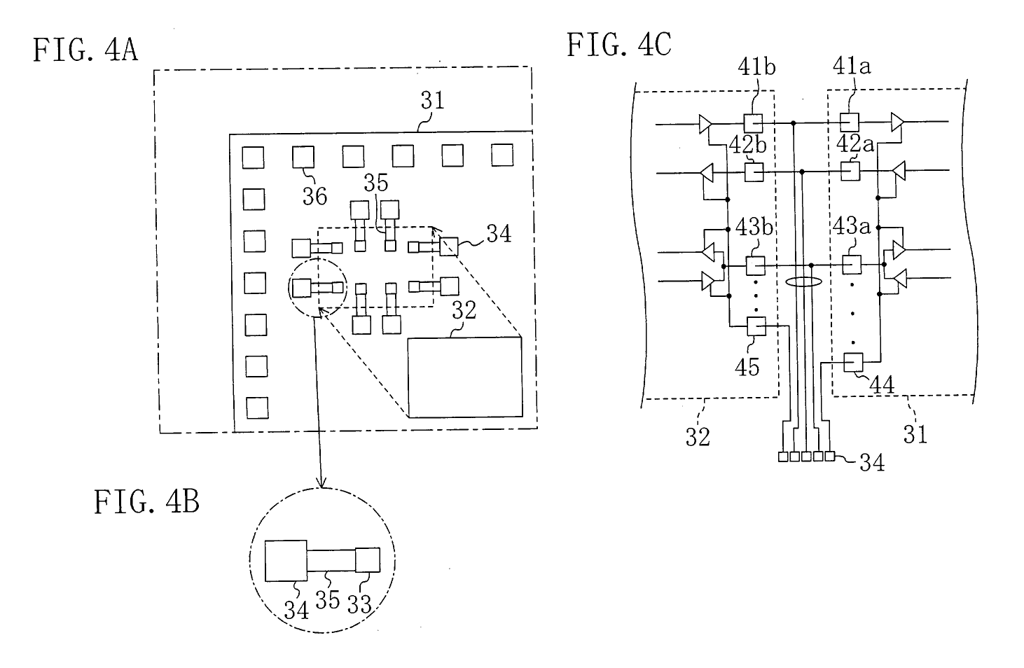

Hereinafter, a third embodiment of the present invention will be described with reference to FIGS. 4A through 4C.

FIGS. 4A and 4B are plan views showing a structure of a semiconductor device with a face-down configuration according to this embodiment. As shown in FIGS. 4A and 4B, the semiconductor device of this embodiment includes: a mother chip 31 with a thickness of 50 to 200 μm; a daughter chip 32 with a thickness of 50 to 200 μm mounted to the mother chip 31; connecting pads 33 in contact with the lower surface (principal surface) of the daughter chip 32; testing pads 34 formed on the mother chip 31; inter-pad wires 35 electrically connecting the connecting pad 33 to the testing pad 34; and externally connecting pad 36 for connecting the mother chip 31 to an external component. In this case, each of the mother and daughter chips 31 and 32 may have a thickness of 50 μm or less.

This structure enables a test to be performed directly on the daughter chip 32 via the testing pad 34 even after the daughter chip 32 has been mounted to the mother chip 31.

FIG. 4C is an electronic circuit diagram showing a configuration of the semiconductor device of this embodiment. As shown in FIG. 4C, in the semiconductor device of this embodiment, the mother chip 31 includes: an input-signal terminal 41a; an output-signal terminal 42a; input/output-signal terminal 43a; and mother-chip-control-signal terminal 44, while the daughter chip 32 includes: an input-signal terminal 41b; an output-signal terminal 42b; input/output-signal terminal 43b; and daughter-chip-control-signal terminal 45.

This configuration allows the mother chip 31 and the daughter chip 32 to be controlled independently from each other. For example, if input, output and input/output signals for the mother chip 31 are set in the HiZ state by sending a control signal for activating only the mother chip 31, it is possible to test the daughter chip 32 alone. On the other hand, if input, output and input/output signals for the daughter chip 32 are set to the HiZ state by sending a control signal for activating only the daughter chip 32, it is possible to test the mother chip 31 alone.

In this manner, in the semiconductor device of this embodiment, it is possible to carry out a test on the daughter chip 32 directly via the testing pads 34 even after the daughter chip 32 has been mounted to the mother chip 31. Specifically, in testing the daughter chip 32, it is possible to input a test pattern to one of the testing pads 34 to output the test pattern from another one of the testing pads 34. This eliminates the necessity of inputting/outputting a test pattern from the mother chip in testing the daughter chip 32, unlike the known devices. As a result, the test pattern can be simplified.

Examples of the test include a test for confirming an electric connection between the mother chip 31 and the daughter chip 32 and a performance test on the daughter chip 32.

For example, in the case where a circuit for processing a picture is included onto the mother chip 31 and a circuit for processing a sound is included onto the daughter chip 32, the use of the testing pads 34 allows the picture and sound to be tested individually simultaneously with the synthesis of the picture and sound. In the case where a logic circuit is included onto the mother chip 31 and a memory is included onto the daughter chip 32, it is also possible to test the logic circuit and the memory individually.

Embodiment 4

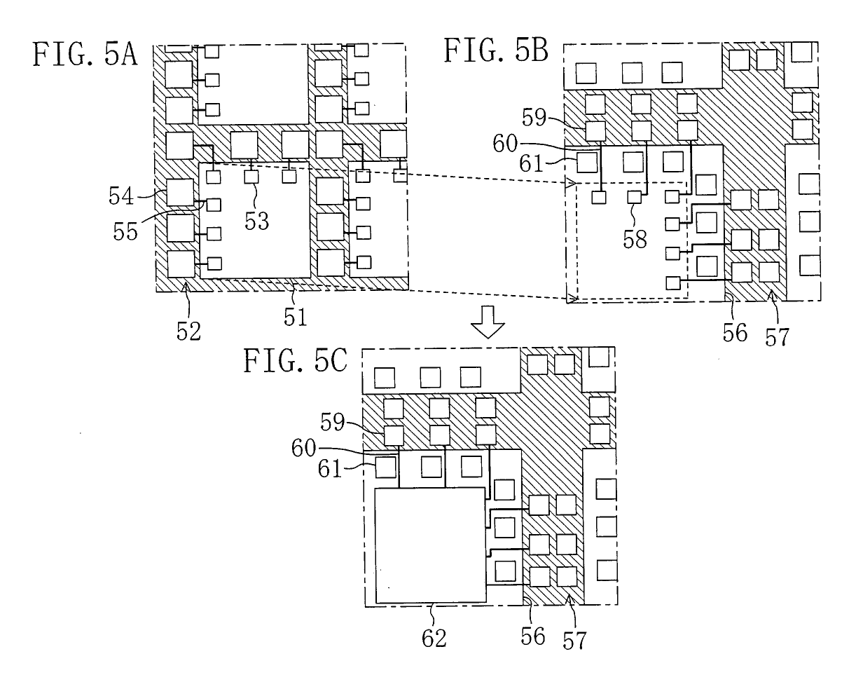

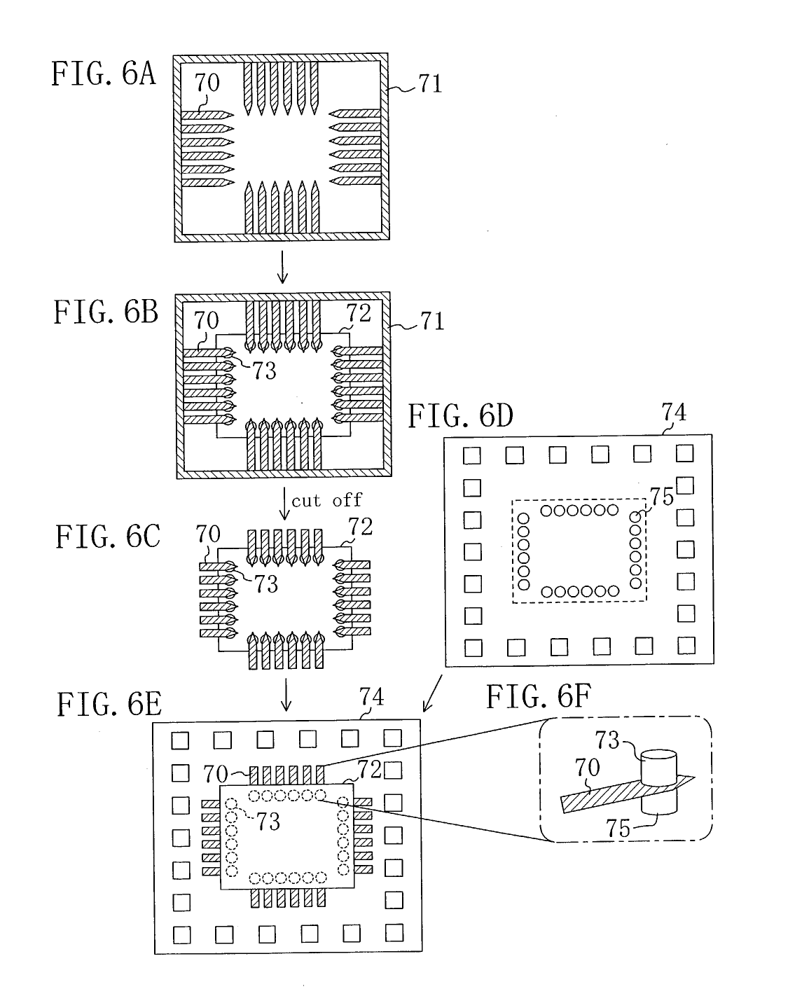

Hereinafter, a semiconductor device with a face-down configuration according to a fourth embodiment of the present invention will be described with reference to FIGS. 5A through 5C.

FIG. 5A is a plan view showing a daughter chip in wafer state according to this embodiment. As shown in FIG. 5A, the wafer is divided into a region where a daughter chip 51 is formed and a scribe lane 52 where no daughter chip 51 is formed. Connecting pads 53 are formed on the daughter chip 51, while testing pads 54 are formed on the scribe lane 52. The connecting pads 53 and the testing pads 54 are electrically connected via inter-pad wires 55.

With this configuration, it is possible to test the daughter chip 51 using the testing pads 54 in wafer state, and it is also possible to separate the daughter chip 51 from the scribe lane 52 after the test. Therefore, an electrical connection is established between the small connecting pads 53 and the testing pads 54 on the scribe lane 52, thus eliminating the necessity of providing large testing pads within the daughter chip 51. As a result, the area of the daughter chip 51 can be reduced.

FIG. 5B is a plan view showing a mother chip in wafer state according to this embodiment. In this state, a daughter chip (now shown) has not yet been mounted on a mother chip. As shown in FIG. 5B, the wafer is divided into a region where a mother chip 56 is formed and a scribe lane 57 where no mother chip 56 is formed. Connecting pads 58 are formed on the mother chip 56, while testing pads 59 are formed on the scribe lane 57. The connecting pads 58 and the testing pads 59 are electrically connected to each other via inter-pad wires 60. Externally connecting pads 61 are formed on the mother chip 56.

With this configuration, it is possible to test the mother chip 56 using the testing pads 59 in wafer state, and it is also possible to separate the mother chip 56 from the scribe lane 57 after the test. This eliminates the necessity of providing the testing pads 59 within the mother chip 56. As a result, the area of the mother chip 56 can be reduced. In addition, the area in the mother chip 56 for mounting a daughter chip (now shown) can be enlarged.

FIG. 5C is a cross-sectional view showing a state in which a daughter chip 62 is mounted to the mother chip 56 formed in the wafer shown in FIG. 5B. With the configuration shown in FIG. 5C, it is possible to carry out a test with the daughter chip 62 mounted to the mother chip 56 in wafer state, and it is also possible to separate the mother chip 56 from the scribe lane 57 after the test. As a result, the area of the mother chip 56 can be reduced. In addition, the use of the testing pads 59 allows a direct test on the daughter chip 62 and a test on the whole of the chips even after the daughter chip 62 has been mounted.

In the configuration shown in FIG. 5C, the daughter chip 51 shown in FIG. 5A may be mounted.

Embodiment 5

Hereinafter, a semiconductor device with a face-down configuration according to a fifth embodiment of the present invention will be described with reference to FIGS. 6A through 6F. FIGS. 6A through 6F are plan views and a perspective view showing process steps for mounting a daughter chip to a mother chip in a process for fabricating the semiconductor device of this embodiment.

FIG. 6A shows a testing lead frame 71 including testing leads 70 of a conductor for use in this embodiment.

In a process step shown in FIG. 6B, the testing lead frame 71 is mounted on a daughter chip 72 with a thickness of 50 to 200 μm. In this process step, the testing lead frame 71 is mounted such that respective portions of the testing leads 70 near their ends are in contact with daughter-chip-side connecting bumps 73 provided on the daughter chip 72.

Next, in a process step shown in FIG. 6C, the testing leads 70 are cut off from the testing lead frame 71.

FIG. 6D shows a mother chip 74 with a thickness of 50 to 200 μm for use in this embodiment. The mother chip 74 is provided with mother-chip-side connecting bumps 75 to be connected to the daughter-chip-side connecting bumps 73.

Then, in a process step shown in FIG. 6E, the daughter chip 72 is mounted to the mother chip 74. In this case, the daughter chip 72 is mounted such that the testing leads 70 are sandwiched between the mother-chip-side connecting bumps 75 and the daughter-chip-side connecting bumps 73 as shown in FIG. 6F. In this manner, the testing leads 70 are fixed, extending outwardly beyond the area where the daughter chip 72 is formed.

In this embodiment, a test using the testing leads 70 achieves the same advantages as in the third embodiment. Specifically, in testing the daughter chip, it is no longer necessary to input/output a test pattern from the mother chip, unlike the conventional devices. As a result, the test pattern can be simplified and, in addition, the test can be carried out in a situation closer to an actual operation.

In the semiconductor device of this embodiment, circuits similar to those in the third embodiment may be provided.

Each of the mother and daughter chips 74 and 72 of this embodiment may have a thickness of 50 μm or less.

Embodiment 6

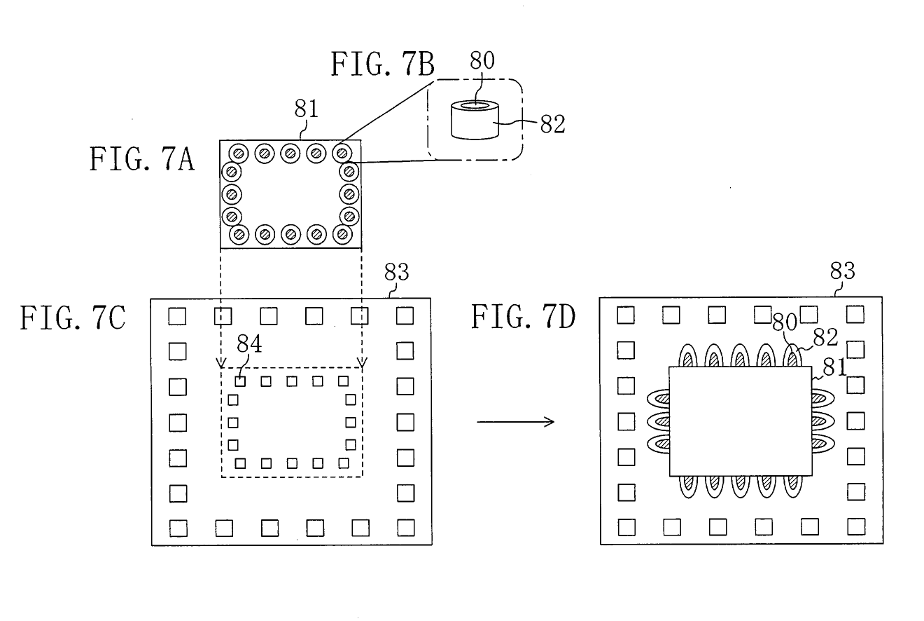

Hereinafter, a semiconductor device with a face-down configuration according to a sixth embodiment of the present invention will be described with reference to FIGS. 7A through 7D. FIGS. 7A through 7D are plan views showing process steps for mounting a daughter chip to a mother chip in a process for fabricating the semiconductor device of this embodiment.

FIG. 7A shows a daughter chip 81 provided with testing leads 80 of a conductor for use in this embodiment. Daughter-chip-side connecting pads (not shown) are formed on part of the surface of the daughter chip 81 near the periphery thereof. Testing leads 80 as shown in FIG. 7B are formed on the daughter-chip-side connecting pads. The respective sides of the testing leads 80 are covered with insulator films 82.

FIG. 7C shows a mother chip 83 for use in this embodiment. The mother chip 83 is provided with mother-chip-side connecting bumps 84 to be connected to the daughter-chip-side connecting pads.

FIG. 7D shows a process step for mounting the daughter chip 81 to the mother chip 83 of this embodiment. After the daughter chip 81 has been mounted, a pressure is applied so as to press the testing leads 80, so that the pressed testing leads 80 are sandwiched between the daughter-chip-side connecting pads and the mother-chip-side connecting pads 84. In this process step, the insulator films 82 expand as the testing leads 80 are pressed to cover the respective sides of the testing leads 80.

In this embodiment, the use of the testing leads 80 achieves the same advantages as in the fifth embodiment without using a complex process. In addition, since the sides of the testing leads 80 are covered with the insulator films 82, it is possible to prevent a short circuit between the testing leads 80.

The semiconductor device of this embodiment may be provided with circuits similar to those in the third embodiment.

Embodiment 7

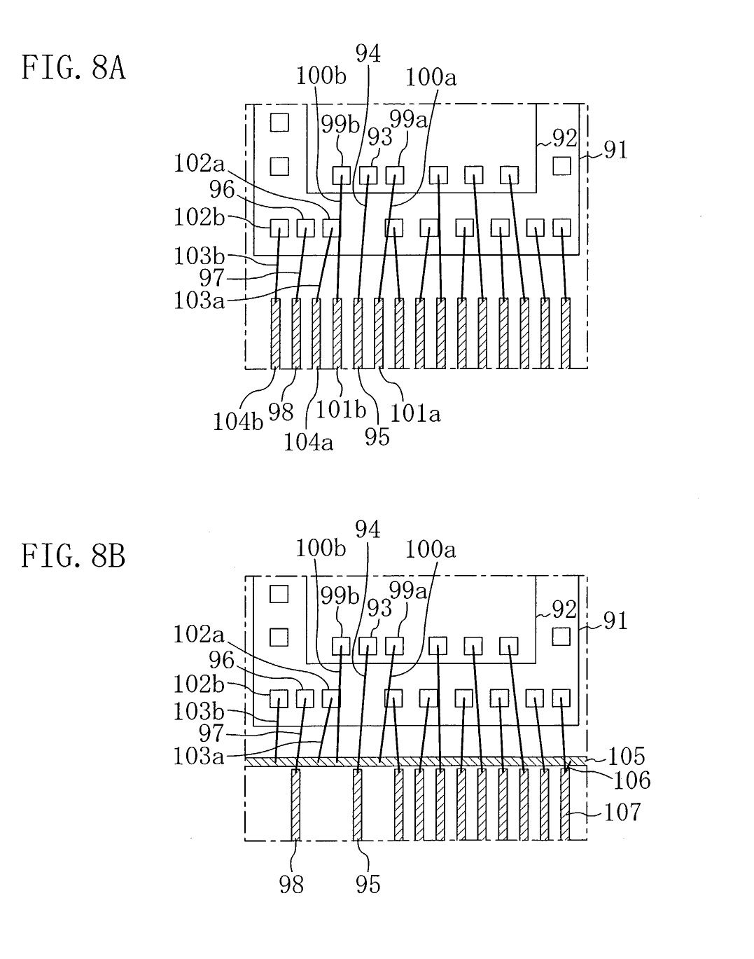

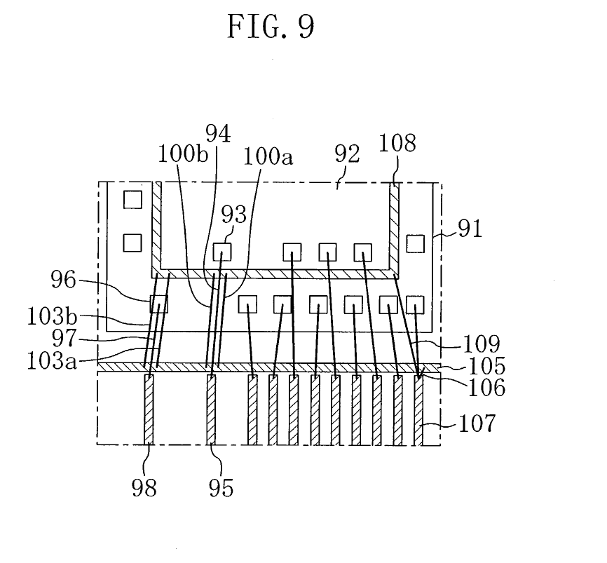

Hereinafter, semiconductor devices with face-up configurations according to a seventh embodiment of the present invention will be described with reference to FIGS. 8A and 8B and FIG. 9. FIGS. 5A and 8B and FIG. 9 are plan views showing structures of the semiconductor devices of this embodiment.

As shown in FIG. 8A, in a first semiconductor device according to this embodiment, a daughter chip 92 is mounted on a mother chip 91. Important-signal pads 93 are formed on the daughter chip 92 and are connected to respective important-signal-wire leads 95 outside the mother chip 91 via important-signal wires 94. Important-signal pads 96 are formed on the mother chip 91 and are connected to respective important-signal-wire leads 98 outside the mother chip 91 via important-signal wires 97.

Shield pads 99a and 99b are formed at both sides of each of the important-signal pads 93 on the daughter chip 92 and are connected to leads 101a and 101b outside the mother chip 91 via bonding wires 100a and 100b, respectively. The leads are connected to a power source line (V_{DD} or V_{SS}). In this manner, each of the important-signal wires 94 is sandwiched between the bonding wires 100a and 100b.

Shield pads 102a and 102b are formed at both sides of each of the important-signal pads 96 on the mother chip 91 and are connected to leads 104a and 104b outside the mother chip 91 via the bonding wires 103a and 103b, respectively. In this manner, each of the important-signal wires 97 is sandwiched between the bonding wires 103a and 103b.

In the semiconductor device shown in FIG. 8A, each of the important-signal wires 94 and 97 is sandwiched between the bonding wires, so that the bonding wires serve as shields. As a result, the important-signal wires 94 and 97 are less affected by noise from the surroundings.

As shown in FIG. 8B, a second semiconductor device according to this embodiment has a structure in which a power source ring 105 is provided in addition to the structure shown in FIG. 8A. The power source ring 105 is connected to power source supply leads 107 via the bonding wires 106. The power source supply leads 107 are connected to a power source line (V_{DD} or V_{SS}). The bonding wires 100a, 100b, 103a and 103b, which are connected to external leads in the structure shown in FIG. 8A, are connected to the power source ring 105.

In this manner, as in the structure shown in FIG. 8A, the bonding wires act as shields, so that the important-signal wires 94 and 97 are less affected by noise from the surroundings. In addition, the number of leads can be reduced, as compared to the structure shown in FIG. 8A.

As shown in FIG. 9, a third semiconductor device according to this embodiment has a structure in which a conductor film 108 is sandwiched between the mother chip 91 and the daughter chip 92 in addition to the structure shown in FIG. 8B. This conductor film 108 is the same as the conductor film 17 in the semiconductor device shown in FIG. 1E.

The conductor film 108 extends outwardly beyond the area where the daughter chip 92 is formed, i.e., is exposed on the mother chip 91. The conductor film 108 is connected to the power source supply lead 107 via bonding wires 109. The bonding wires 100a, 100b, 103a and 103a, which are connected to the shield pads in the structure shown in FIG. 8B, are connected to the conductor film 108.

In this manner, as in the structure shown in FIG. 8B, the bonding wires act as shields, so that the important-signal wires 94 and 97 are less affected by noise from the surroundings. In addition, the number of shield pads formed on the daughter chip 92 and the mother chip 91 can be reduced, as compared to the structure shown in FIG. 8B. Further, as in the semiconductor device shown in FIG. 1E, it is possible to prevent the noise radiation from the mother chip 91 from affecting the daughter chip 92.

In this embodiment, the case where the semiconductor device has the face-up configuration has been described. However, this embodiment is applicable to an electric connection between a mother chip and a daughter chip in the case of a face-down configuration.

In this embodiment, bonding wires serving as shields are provided for both of the important-signal wires connecting the mother chip to the leads and the important-signal wires connecting the daughter chip to the leads. However, bonding wires serving as shields may be provided for either the important-signal wires connecting the mother chip to the leads or the important-signal wires connecting the daughter chip to the leads

In this embodiment, the daughter chip is provided on the mother chip. However, this embodiment is applicable to the case where a semiconductor chip is provided on a base (such as a substrate).

Embodiment 8

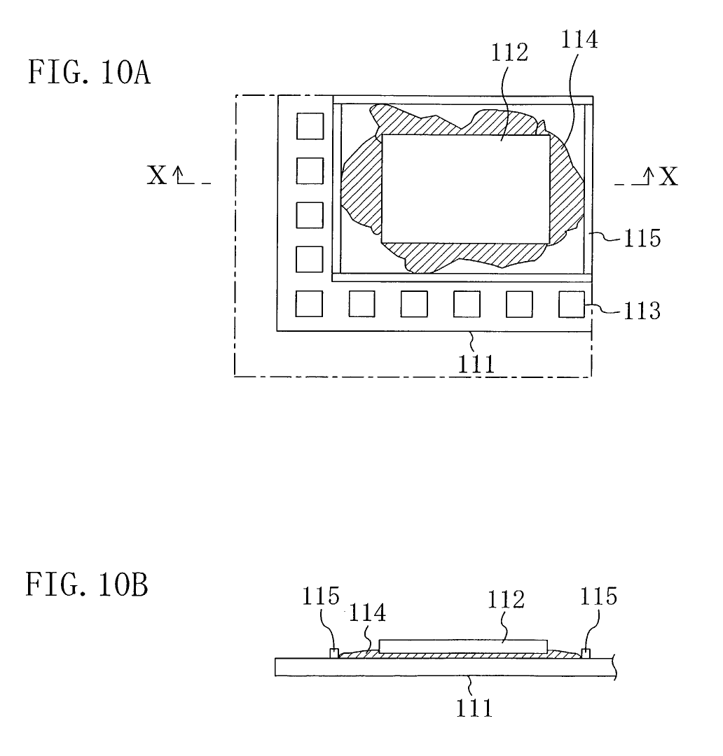

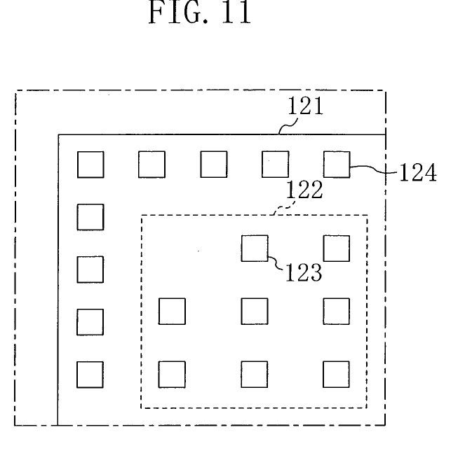

Hereinafter, a semiconductor device with a face-up configuration according to an eighth embodiment of the present invention will be described with reference to FIGS. 10A and 10B. FIGS. 10A and 10B are respectively a plan view and a cross-sectional view taken along the line X-X and show a structure of the semiconductor device of this embodiment.

As shown in FIGS. 10A and 10B, in the semiconductor device of this embodiment, a daughter chip 112 is mounted on a mother chip 111 including externally connecting pads 113 with the chips 112 and 113 placed face-to-face. The mother chip 111 and the daughter chip 112 are bonded together with a glue (an adhesive) 114. A glue stopper 115 is formed on the mother chip 111 so as to prevent the glue 114 from expanding. Although not shown in FIGS. 10A and 10B, the daughter chip 112 is electrically connected to an external component via bonding wires, for example.

In this embodiment, the glue stopper 115 blocks expansion of the glue 114 when the mother chip 111 and the daughter chip 112 are bonded together. Thus, it is possible to prevent the externally connecting pads 113, for example, on the mother chip 111 from being contaminated by the glue 114. In addition, the glue stopper 115 allows the daughter chip 112 to be disposed closer to the externally connecting pads 113, so that it is possible to increase the mounting area in the mother chip 111 for the daughter chip.

The glue stopper 115 may be removed after the bonding of the daughter chip 112 or may remain without change after the bonding.

Embodiment 9

Hereinafter, a semiconductor device with a face-up configuration according to a ninth embodiment of the present invention will be described with reference to FIG. 11.

FIG. 11 is a plan view showing a mother chip before a daughter chip is mounted thereto. As shown in FIG. 11, daughter-chip connecting pads 123 are formed on a daughter-chip mounting region 122 of a mother chip 121 to which a daughter chip is to be mounted. Externally connecting pads 124 are formed on a region of the mother chip 121 other than the daughter-chip mounting region 122.

The daughter-chip connecting pads 123 are arranged so as to determine the orientation uniquely when viewed from above. Specifically, the orientation is identified by providing no pad at one of the four corners of the daughter-chip mounting region 122.

In this manner, it is possible to prevent the daughter chip from being mounted in a wrong orientation.

In the inventive semiconductor devices, the influence of radiation noise can be reduced, heat radiation can be improved, and moreover, the substrate potential can be stabilized.

In addition, in the semiconductor devices with the face-down configurations, it is possible to test the daughter chip alone directly. Further, the area for chips in a wafer is secured more effectively.

In the semiconductor devices with the face-up configurations, it is possible to suppress the influence of noise on wires for transmitting important signals. In addition, it is also possible to prevent contamination by the glue and misidentification of the chip orientation during bonding.

What is claimed is:

1. A semiconductor device comprising:
a first semiconductor chip;
a second semiconductor chip mounted to the first semiconductor chip; and
a conductor film formed on a back surface of the second semiconductor chip and electrically connected to a connecting member connected to a potential-stabilizing member.

2. The semiconductor device of claim 1, wherein the second semiconductor chip is mounted to the first semiconductor chip with a principal surface of the second semiconductor chip facing downward.

3. The semiconductor device of claim 2, wherein the conductor film extends from on the back surface of the second semiconductor chip onto a portion of the first semiconductor chip.

4. The semiconductor device of claim 1, wherein the second semiconductor chip is mounted to the first semiconductor chip with a principal surface of the second semiconductor chip facing upward,
part of the conductor film is sandwiched between the first and second semiconductor chips, and
the other part of the conductor film is exposed on the first semiconductor chip and is in contact with the connecting member.

5. The semiconductor device of claim 1, wherein the second semiconductor chip is provided in a plural presence over the first semiconductor chip, and
the conductor film covers the back surfaces of the plurality of second semiconductor chips.

6. A semiconductor device, comprising:
a first semiconductor chip;
a conductor pattern provided on the top of the first semiconductor chip and electrically connected to a potential-stabilizing member;
a first-chip-side connecting pad provided on the top of the first semiconductor chip and insulated from the conductor pattern;
a second semiconductor chip mounted to the first semiconductor chip with a principal surface of the second semiconductor chip facing downward; and
a second-chip-side connecting pad provided on the bottom of the second semiconductor chip and electrically connected to the first-chip-side connecting pad,
wherein the conductor pattern and the first-chip-side connecting pad are patterned out of an identical film.

7. The semiconductor device of claim 6, wherein the potential-stabilizing member is a power source line for the first semiconductor chip.

8. A semiconductor device, comprising:
a first semiconductor chip;
a second semiconductor chip mounted to the first semiconductor chip with a principal surface of the second semiconductor chip facing downward; and
a second-chip-side connecting member provided on the bottom of the second semiconductor chip; and
a testing member electrically connected to the second-chip-side connecting member, at least part of the second-chip-side connecting member being located outside the second semiconductor chip when viewed vertically to the second semiconductor chip.

9. The semiconductor device of claim 8, wherein the part of the testing member is located in a peripheral portion of the second semiconductor chip when viewed vertically to the second semiconductor chip, and
the second semiconductor chip is accessible to external equipment with the testing member.

10. The semiconductor device of claim 8, wherein the testing member is formed on the top of the first semiconductor chip, and
the testing member is connected to the second-chip-side connecting member via a wire.

11. The semiconductor device of claim 8, wherein a first-chip-side connecting member is provided on the top of the first semiconductor chip, and
the part of the testing member extends outwardly beyond a region of the first semiconductor chip where the second semiconductor chip is formed, and the other part of the testing member is sandwiched between the first-chip-side connecting member and the second-chip-side connecting member.

12. The semiconductor device of claim 11, wherein part of the testing member is covered with an insulator film.

13. The semiconductor device of claim 8, including a circuit for activating the first and second semiconductor chips individually in accordance to signals applied to the testing member.

14. A semiconductor device, comprising:
a first semiconductor chip;
a second semiconductor chip mounted to the first semiconductor chip with a principal surface of the second semiconductor chip facing downward;
a second-chip-side connecting member provided on the top of the second semiconductor chip; and
a wire, which is connected to the second-chip-side connecting member and was located on a scribe lane in a wafer state.

15. A semiconductor device, comprising:
a first semiconductor chip;
a first-chip-side connecting member provided on the top of the first semiconductor chip;
a second semiconductor chip mounted to the first semiconductor chip with a principal surface of the second semiconductor chip facing downward; and
a wire, which is connected to the first-chip-side connecting member and was located on a scribe lane in a wafer state.

16. A semiconductor device, comprising:
a base;
a semiconductor chip mounted on the base;
first and second terminals provided on part of the semiconductor chip;
a signal-transmitting wire having two terminals, one of which is connected to the first terminal and the other of which is connected to a first external terminal; and
one or more shield wires for removing noise in the signal-transmitting wire, each of the shield wires being located at a side of the signal-transmitting wire and having two terminals, one of which is connected to the second terminal and the other of which is connected to a second external terminal.

17. The semiconductor device of claim 16, wherein the signal-transmitting wire is sandwiched between the shield wires.

18. The semiconductor device of claim 16, wherein the base is a second semiconductor chip;
third and fourth terminals are further provided on parts of the second semiconductor chip,
the third terminal is connected to a second signal-transmitting wire having a terminal connected to a third external terminal, and
one or more second shield wires for protecting the second signal-transmitting wire is further provided, and each of the second shield wires is located at a side of the second signal-transmitting wire and has two terminals, one of which is connected to the fourth terminal and the other is connected to a fourth external terminal.

19. The semiconductor device of claim 18, wherein the second and fourth external terminals are in an identical power source ring connected to a power source line.

20. The semiconductor device of claim 18, wherein the second and fourth terminals are made of an identical conductor film intervening between the semiconductor chip and the second semiconductor chip.

21. A semiconductor device, comprising:
a first semiconductor chip;
a second semiconductor chip mounted to the first semiconductor chip;
an adhesive for bonding the first and second semiconductor chips together; and
an adhesive stopper for preventing the adhesive from expanding, the adhesive stopper being formed on the first semiconductor chip.

22. A semiconductor device, comprising:
a first semiconductor chip;
a second semiconductor chip mounted to the first semiconductor chip; and
a connecting member for identifying an orientation of the first semiconductor chip when viewed vertically to the first semiconductor chip, the connecting member being formed on the first semiconductor chip.

23. A method for fabricating a semiconductor device in which a second semiconductor chip is mounted to a first semiconductor chip, the method comprising the steps of:
a) forming a first-chip-side connecting member on part of the first semiconductor chip;
b) forming a second-chip-side connecting member on part of the second semiconductor chip; and
c) mounting the second semiconductor chip to the first semiconductor chip with part of a testing member sandwiched between the first-chip-side connecting member and the second-chip-side connecting member.

24. The method of claim 23, wherein at least part of the side of the testing member is covered with an insulator film, and
in the step c), the second semiconductor chip is mounted to the first semiconductor chip with a pressure applied thereto.
